(19) United States
(12) Patent Application Publication
(10) Pub. No.: US 2023/0133670 A1
(43) Pub. Date: May 4, 2023

(54) IMAGE SENSING DEVICE

(71) Applicant: SK hynix Inc., Icheon-si (KR)

(72) Inventors: Kyoung In LEE, Icheon-si (KR); Won Je PARK, Icheon-si (KR); Byoung Gyu KIM, Icheon-si (KR)

(21) Appl. No.: 17/978,759

(22) Filed: Nov. 1, 2022

(30) Foreign Application Priority Data
Nov. 1, 2021 (KR) 10-2021-0148003

(51) Int. Cl. H01L 27/146

(52) U.S. Cl. CPC H01L 27/14623; H01L 27/14605; H01L 27/1462; H01L 27/1463

(57) ABSTRACT

This patent document discloses embodiments of image sensing devices including, an image sensing device which includes a substrate including a substrate surface and a trench extending from the substrate surface, a plurality of photoelectric conversion elements formed in the substrate and operable to convert incident light into photocharge, an electrode formed in the trench and configured to receive a bias voltage for suppressing a dark current, and a light blocking layer formed over the substrate surface of the substrate to block light from transmitting therethrough, and configured to be electrically conductive to receive the bias voltage and transmit the received bias voltage to the electrode.

### CROSS-REFERENCE TO RELATED APPLICATION

This patent document claims the priority and benefits of Korean patent application No. 10-2021-0148003, filed on Nov. 1, 2021, the disclosure of which is incorporated herein by reference in its entirety as part of the disclosure of this patent document.

### TECHNICAL FIELD

The technology and implementations disclosed in this patent document generally relate to an image sensing device including one or more pixels capable of sensing incident light by generating an electrical signal corresponding to the intensity of incident light.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device that includes a deep trench isolation (DTI) layer such as a backside DTI (BDTI), thereby reducing optical crosstalk between adjacent pixels.

In an embodiment of the disclosed technology, an image sensing device may include a substrate including a substrate surface and a trench extending from the substrate surface, a plurality of photoelectric conversion elements formed in the substrate and operable to convert incident light into photocharge, an electrode formed in the trench and configured to receive a bias voltage for suppressing a dark current, and a light blocking layer formed over the substrate surface of the substrate to block light from transmitting therethrough, and configured to be electrically conductive to receive the bias voltage and transmit the received bias voltage to the electrode.

In another embodiment of the disclosed technology, an image sensing device may include a pixel array including an active pixel region and an optical black pixel region, the active pixel region including a plurality of active pixels that receive incident light and generate a signal that indicates an intensity of the received incident light, the optical black pixel region including a plurality of optical black pixels that include a light blocking layer to block light from entry and generate a signal independent of the intensity of the incident light received by the optical black pixel, an electrode structured to include vertically extended portions disposed between adjacent pixels of active pixels and optical black pixels, and configured to receive a bias voltage for suppressing a dark current generated in at least one of the active pixel region or the optical black pixel region, and a bias generator configured to generate the bias voltage, wherein the light blocking layer in the optical black pixel region is configured to be electrically conductive to receive the bias voltage from the bias generator and transmit the received bias voltage to the electrode.

In an embodiment of the disclosed technology, an image sensing device may include a substrate including a plurality of photoelectric conversion elements, each of which generates photocharges corresponding to incident light, a deep trench isolation (DTI) electrode disposed in a DTI structure recessed from one surface of the substrate, and configured to receive a bias voltage, a bias generator configured to generate the bias voltage, and a light blocking layer spaced apart from the one surface of the substrate, and configured to receive the bias voltage from the bias generator and transmit the received bias voltage to the DTI electrode.

In another embodiment of the disclosed technology, an image sensing device may include a pixel array, a deep trench isolation

(DTI) electrode, a bias generator, and a light blocking layer. The pixel array may include an active pixel region including a plurality of active pixels, each of which generates a signal corresponding to intensity of the incident light, and an optical black pixel region including a plurality of optical black pixels, each of which generates a signal independent of the intensity of the incident light. The DTI electrode disposed between adjacent pixels from among the active pixels and the optical black pixels may be configured to receive a bias voltage. The bias generator may generate the bias voltage. The light blocking layer disposed in the optical black pixel region may be configured to receive the bias voltage from the bias generator and transmit the received bias voltage to the DTI electrode.

The above and other embodiments and various aspects and features of the disclosed technology are described in greater detail in the drawings, the description and claims.

### N OF THE DRAWINGS

FIG. 1 is a block diagram illustrating an example of an image sensing device based on some implementations of the disclosed technology.

FIG. 2 is a schematic diagram illustrating an example of a pixel array shown in FIG. 1 based on some implementations of the disclosed technology.

FIG. 3 is a schematic diagram illustrating another example of the pixel array shown in FIG. 1 based on some implementations of the disclosed technology.

FIG. 4 is a circuit diagram illustrating an example of an active pixel or an optical black pixel included in the pixel array shown in FIG. 2 or FIG. 3 based on some implementations of the disclosed technology.

FIG. 5 is an example of a first cross-section of the pixel array shown in FIG. 2 or FIG. 3 based on some implementations of the disclosed technology.

FIG. 6 is an example of a second cross-section of the pixel array shown in FIG. 2 or FIG. 3 based on some implementations of the disclosed technology.

FIG. 7 is a schematic diagram illustrating an example of the pixel array based on some implementations of the disclosed technology.

### DETAILED DESCRIPTION

This patent document provides implementations and examples of an image sensing device including one or more pixels capable of sensing incident light by generating an electrical signal corresponding to the intensity of incident light, that may be used in configurations to substantially address one or more technical or engineering issues and to mitigate limitations or disadvantages encountered in some other image sensing devices. Some implementations of the disclosed technology relate to an image sensing device for reducing optical crosstalk between adjacent pixels. The disclosed technology provides various implementations of an image sensing device having an optimum structure for reducing crosstalk between pixels.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

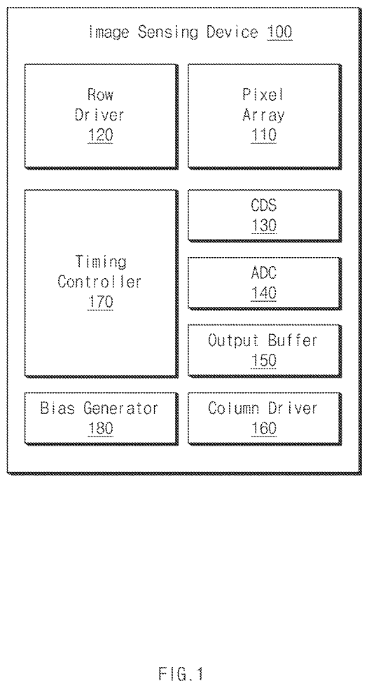

FIG. 1 is a block diagram illustrating an image sensing device 100 according to an embodiment of the disclosed technology.

Referring to FIG. 1, the image sensing device 100 may include a pixel array 110, a row driver 120, a correlated double sampler (CDS) 130, an analog-digital converter (ADC) 140, an output buffer 150, a column driver 160, and a timing controller 170, and a bias generator 180. The components of the image sensing device 100 illustrated in FIG. 1 are discussed by way of example only, and this patent document encompasses numerous other changes, substitutions, variations, alterations, and modifications.

The pixel array 110 may include a plurality of pixels arranged in rows and columns. In one example, the plurality of pixels can be arranged in a two dimensional pixel array including rows and columns. In another example, the plurality of unit imaging pixels can be arranged in a three dimensional pixel array. The plurality of pixels may convert an optical signal into an electrical signal on a pixel basis or a pixel group basis, where pixels in a pixel group share at least certain internal circuitry. The pixel array 110 may receive driving signals, including a row selection signal, a pixel reset signal and a transmission signal, from the row driver 120. Upon receiving the driving signal, corresponding pixels in the pixel array 110 may be activated to perform the operations corresponding to the row selection signal, the pixel reset signal, and the transmission signal.

The row driver 120 may activate the pixel array 110 to perform certain operations on the pixels in the corresponding row based on commands and control signals provided by controller circuitry such as the timing controller 170. In some implementations, the row driver 120 may select one or more pixels arranged in one or more rows of the pixel array 110. The row driver 120 may generate a row selection signal to select one or more rows among the plurality of rows. The row driver 120 may sequentially enable the pixel reset signal for resetting imaging pixels corresponding to at least one selected row, and the transmission signal for the pixels corresponding to the at least one selected row. Thus, a reference signal and an image signal, which are analog signals generated by each of the imaging pixels of the selected row, may be sequentially transferred to the CDS 130. The reference signal may be an electrical signal that is provided to the CDS 130 when a sensing node of a pixel (e.g., floating diffusion node) is reset, and the image signal may be an electrical signal that is provided to the CDS 130 when photocharges generated by the pixel are accumulated in the sensing node. The reference signal indicating unique reset noise of each pixel and the image signal indicating the intensity of incident light may be generically called a pixel signal as necessary.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

In some implementations, the CDS 130 may transfer the reference signal and the image signal of each of the columns as a correlate double sampling signal to the ADC 140 based on control signals from the timing controller 170.

The ADC 140 is used to convert analog CDS signals into digital signals. In some implementations, the ADC 140 may be implemented as a ramp-compare type ADC. The ramp-compare type ADC may include a comparator circuit for comparing the analog pixel signal with a reference signal such as a ramp signal that ramps up or down, and a timer counts until a voltage of the ramp signal matches the analog pixel signal. In some embodiments of the disclosed technology, the ADC 140 may convert the correlate double sampling signal generated by the CDS 130 for each of the columns into a digital signal, and output the digital signal. The ADC 140 may perform a counting operation and a computing operation based on the correlate double sampling signal for each of the columns and a ramp signal provided from the timing controller 170. In this way, the ADC 140 may eliminate or reduce noises such as reset noise arising from the imaging pixels when generating digital image data.

The ADC 140 may include a plurality of column counters. Each column of the pixel array 110 is coupled to a column counter, and image data can be generated by converting the correlate double sampling signals received from each column into digital signals using the column counter. In another embodiment of the disclosed technology, the ADC 140 may include a global counter to convert the correlate double sampling signals corresponding to the columns into digital signals using a global code provided from the global counter.

The output buffer 150 may temporarily hold the column-based image data provided from the ADC 140 to output the image data. In one example, the image data provided to the output buffer 150 from the ADC 140 may be temporarily stored in the output buffer 150 based on control signals of the timing controller 170. The output buffer 150 may provide an interface to compensate for data rate differences or transmission rate differences between the image sensing device 100 and other devices.

The column driver 160 may select a column of the output buffer upon receiving a control signal from the timing controller 170, and sequentially output the image data, which are temporarily stored in the selected column of the output buffer 150. In some implementations, upon receiving an address signal from the timing controller 170, the column driver 160 may generate a column selection signal based on the address signal and select a column of the output buffer 150, outputting the image data from the selected column of the output buffer 150 as an output signal.

The timing controller 170 may control operations of at least one of the row driver 120, the ADC 140, the output buffer 150, the column driver 160, and a bias generator 180.

The timing controller 170 may provide clock signals for the row driver 120, the CDS 130, the ADC 140, the output buffer 150, the column driver 160, and the bias generator 180 to perform the operations of the image sensing device 100. In some implementations, the timing controller 170 may also provide control signals for timing control, address signals for selecting a row or column, and control signals for controlling a level of a bias voltage applied to the pixel array 110. In an embodiment of the disclosed technology, the timing controller 170 may include a logic control circuit, a phase lock loop (PLL) circuit, a timing control circuit, a communication interface circuit and others.

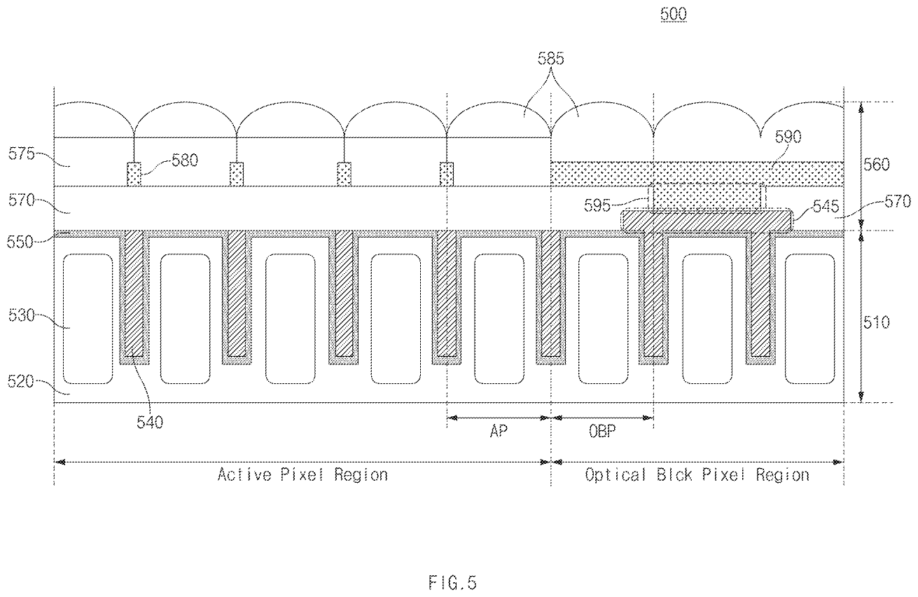

The bias generator 180 may generate a bias voltage and suppress a dark current that would have been generated in a pixel of the pixel array 110 by applying the bias voltage to the pixel array 110 as will be discussed below with reference to FIG. 5.

The bias voltage may be determined by performing a wafer probe test process on the image sensing device 100 and stored in a one-time programmable memory (OTP) memory. For example, the bias voltage may be experimentally determined in a way that can minimize unnecessary power consumption and maximize the dark current suppression without deteriorating the performance of the image sensing device 100.

The bias generator 180 may generate a voltage corresponding to a bias voltage stored in the OTP memory. In some implementations, the OTP memory may be included in the image sensing device 100. In one example, the OTP memory may be included in the bias generator 180.

In some implementations, the bias voltage may include a plurality of values.

For example, the plurality of values may correspond to a plurality of operation modes of the image sensing device 100, respectively. A dark current generated under a low-luminance condition may be different from a dark current generated under a high-luminance condition. In order to effectively suppress the dark current in each environment, a bias voltage provided from the bias generator 180 may vary depending on the operation mode.

Alternatively, the plurality of values may correspond to the plurality of regions of the pixel array 110, respectively. The dark currents generated due to the positions of the respective pixels in the pixel array 110 may be different from each other. In order to effectively suppress the dark current regardless of the position of each pixel, the bias voltage generated by the bias generator 180 may vary depending on the respective regions.

In some implementations, the bias voltage may be a negative voltage.

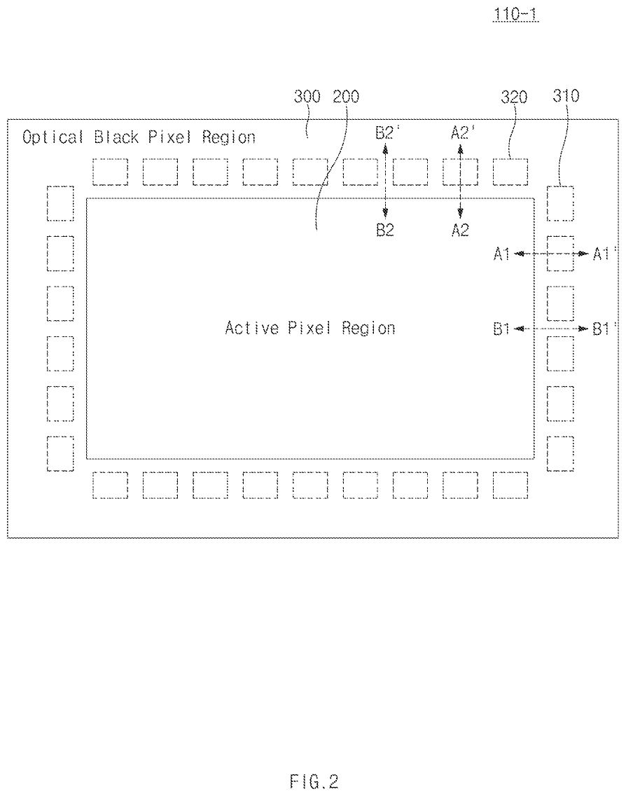

FIG. 2 is a schematic diagram illustrating one example of the pixel array shown in FIG. 1 based on some implementations of the disclosed technology.

Referring to FIG. 2, the pixel array 110-1 may include an active pixel region 200 and an optical black pixel region 300.

The active pixel region 200 may include a plurality of active pixels arranged in a matrix array having a plurality of rows and a plurality of columns. Each active pixel may be a pixel that converts an incident light signal into an electrical signal as described in FIG. 1.

The optical black pixel region 300 may be disposed to surround at least a portion of the active pixel region 200. Each optical black pixel region 300 may include at least one optical black pixel corresponding to the active pixel. The optical black pixel may be a pixel for acquiring a dark level signal that does not indicate the incident light. For example, the dark level signal may have a certain value regardless of the intensity of the incident light. The optical black pixel has a structure that is similar or identical to an active pixel belonging to the same row or the same column, and may operate by the same pixel control signal as the active pixel belonging to the same row or the same column. Unlike the active pixel, however, the optical black pixel may have a light shielding or blocking structure to block light. That is, a signal generated by the optical black pixel may correspond to a signal indicating dark noise generated due to other factors (e.g., temperature, a unique pixel structure, etc.) other than incident light.

Image data of the active pixel may be obtained by calculating (e.g., subtracting) an average value of dark level signals generated by at least one optical black pixel (e.g., an optical black pixel belonging to the same row or the same column as the active pixel), so that image data can only include values that is obtained by the incident light. In some implementations, such a calculation process may be performed by the image signal processor (not shown) configured to receive image data from the image sensing device 100.

The optical black pixel region 300 may include a light blocking layer to block incident light from at least one optical black pixel. The light blocking layer may have a specific area corresponding to the optical black pixel region 300, and may be disposed over the optical black pixel region 300. For example, the light blocking layer may have an area that is sufficiently large to cover the optical black pixel region 300. In various implementations, the light blocking layer may be formed of an electrically conductive material that also blocks light, including, e.g., a metal layer formed by one or more metals or a doped layer that is electrically conductive.

The optical black pixel region 300 may include a first contact region 310 and a second contact region 320. In order for the bias voltage generated by the bias generator 180 to be transferred, each of the first contact region 310 and the second contact region 320 may include a region where the light blocking layer of the optical black pixel region 300 electrically contacts the substrate. The light blocking layer of the optical black pixel region 300 will be described with reference to FIG. 5.

The first contact region 310 may be a region having a length shorter than a left side or a right side of the active pixel region 200. At least one first contact region 310 may be disposed in a column direction (e.g., in the vertical direction of FIG. 2) within the optical black pixel region 300 disposed at one side of the left side and the right side of the active pixel region 200.

The second contact region 320 may be a region having a length shorter than an upper side or a lower side of the active pixel region 200. At least one second contact region 320 may be disposed in a row direction (e.g., in a horizontal direction of FIG. 2) within the optical black pixel region 300 disposed at the upper side or the lower side of the active pixel region 200.

Each of the first contact region 310 and the second contact region 320 may have a relatively short length. The first contact region 310 and the second contact region 320 may be spaced apart from each other, so that each of the first contact region 310 and the second contact region 320 may transmit a bias voltage received from the light blocking layer to the substrate, thereby minimizing the influence of noise that otherwise would have been introduced into a partial region.

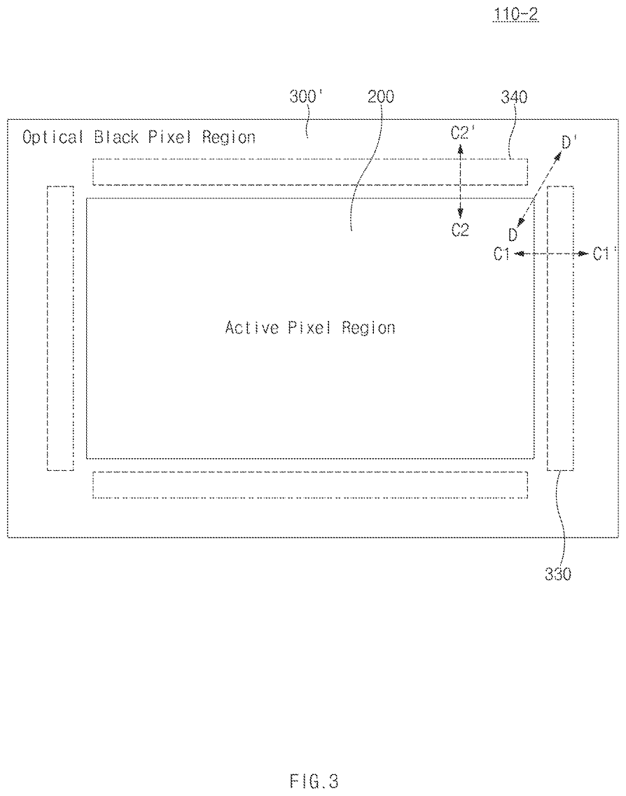

FIG. 3 is a schematic diagram illustrating another example of the pixel array shown in FIG. 1 based on some implementations of the disclosed technology.

Referring to FIG. 3, the pixel array 110-2 may include an active pixel region 200 and an optical black pixel region 300′. In some implementations, the pixel array 110-2 may have a structure that is similar or identical to those of the pixel array 110-1 shown in FIG. 2. In some implementations, the pixel array 110-2 may have characteristics that are different from those of the pixel array 110-1 shown in FIG. 2, as will be discussed below.

The optical black pixel region 300′ may include a third contact region 330 and a fourth contact region 340. Each of the third contact region 330 and the fourth contact region 340 may refer to a region in which the light blocking layer of the optical black pixel region 300′ electrically contacts the substrate.

The third contact region 330 may be a region having a length equal to or longer than the left side or the right side of the active pixel region 200, and the third contact region 330 may be arranged in the column direction within the optical black pixel region 300′ disposed at one of the left side and the right side of the active pixel region 200.

The fourth contact region 340 may be a region having a length equal to or longer than the upper side or the lower side of the active pixel region 200, and the fourth contact region 340 may be arranged in the row direction within the optical black pixel region 300′ disposed at one side of the upper side and the lower side of the active pixel region 200.

Each of the third contact region 330 and the fourth contact region 340 may have a relatively long length, and may transmit a bias voltage received from the light blocking layer of the optical black pixel region 300 to the substrate through a large area. As a result, resistance components for transfer of the bias voltage may be reduced as much as possible, so that performance deterioration caused by reduction of the bias voltage can be prevented.

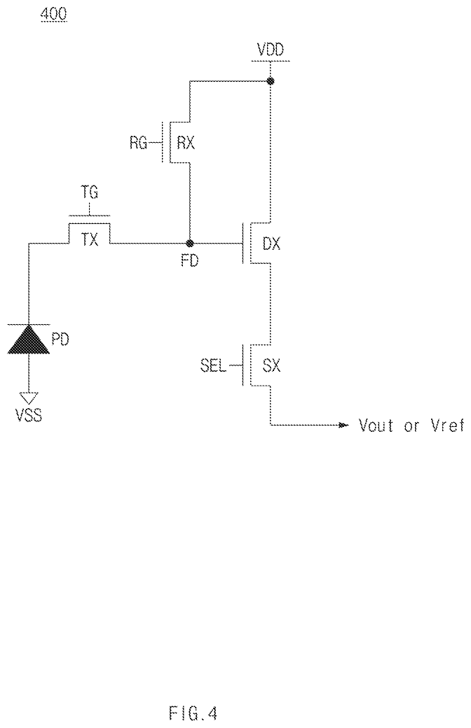

FIG. 4 is a circuit diagram illustrating an example of the active pixel or the optical black pixel included in the pixel array shown in FIG. 2 or FIG. 3.

Referring to FIG. 4, an equivalent circuit 400 of each of the active pixel and the optical black pixel may include a photoelectric conversion element PD, a transfer transistor TX, a reset transistor RX, a drive transistor DX, and a selection transistor SX. Although only a 4TR (i.e., four-transistor) structure is depicted in FIG. 4 for convenience of description, the active pixel or the optical black pixel may include a 3TR (i.e., three-transistor) structure, a 5TR (i.e., five-transistor) structure, or a shared pixel structure in which multiple pixels share at least some transistors.

The photoelectric conversion element PD may accumulate photocharges corresponding to the intensity of incident light. One end of the photoelectric conversion element PD may be coupled to a source voltage VSS, and the other end of the photoelectric conversion element PD may be coupled to one or more transfer transistors TX. In one example, the source voltage VSS may be a ground voltage. In some implementations, the photoelectric conversion element PD may include a phototransistor, a photogate, a pinned photodiode or a combination thereof.

The transfer transistor TX may be coupled between the photoelectric conversion element PD and the floating diffusion node FD. The transfer transistor TX may be turned on or off in response to a transmission control signal TG, so that the transfer transistor TX may transmit photocharges accumulated in the photoelectric conversion element PD to the floating diffusion node FD.

The floating diffusion node FD may accumulate photocharges received from the transfer transistor TX. For example, the floating diffusion node FD may be a region that has a predetermined capacitance such that an electrical potential or voltage may vary depending on the amount of accumulated photocharges. For example, the floating diffusion node FD may be a junction capacitor, and other implementations are also possible.

The reset transistor RX may be coupled between a drain voltage (VDD) terminal and the floating diffusion node FD, and may reset a voltage of the floating diffusion node FD to the drain voltage VDD in response to a pixel reset signal RG. In this case, although the drain voltage VDD may be a power-supply voltage, the scope or spirit of the disclosed technology is not limited thereto.

The drive transistor DX may amplify a change in the electric potential or voltage of the floating diffusion node FD that has received the photocharges accumulated in the photoelectric conversion element PD, and may transmit the amplified photocharges to the selection transistor SX. In other words, the drive transistor DX may operate as a source follower transistor.

The selection transistor SX may select at least one pixel to be read in units of a row. The selection transistor SX may be turned on by a selection control signal SEL, so that the signal corresponding to the electric potential change of the floating diffusion node FD provided to the selection transistor SX can be output as an output voltage Vout or Vref.

The output voltage Vout or Vref of the selection transistor SX may correspond to a reference signal (e.g., a signal corresponding to the reset floating diffusion node FD) depicted in FIG. 1 and an image signal (e.g., a signal corresponding to the floating diffusion node FD in which photocharges received from the photoelectric conversion element PD are accumulated).

However, if the equivalent circuit 400 corresponds to the optical black pixel, this means that the optical black pixel operates in the same manner as in the active pixel and the incident light is blocked by the light blocking layer, so that the photoelectric conversion element PD may be configured in a manner that the incident light generates photoelectric conversion photocharges and photocharges caused by the noise factors (e.g., temperature, a unique pixel structure, etc.) can be accumulated in the photoelectric conversion element PD.

FIG. 5 is a cross-sectional view illustrating an example of a first cross-section 500 of the pixel array shown in FIG. 2 or FIG. 3.

Referring to FIG. 5, the first cross-section 500 may correspond to a cross-section of the pixel array 110-1 taken along line A1-A1′ or A2-A2′ depicted in the pixel array 110-1 of FIG. 2. Alternatively, the first cross-section 500 may correspond to a cross-section of the pixel array 110-2 taken along line C1-C1′ or C2-C2′ depicted in the pixel array 110-2 of FIG. 3. The line A1-A1′ or A2-A2′ or the line C1-C1′ or C2-C2′ may be a hypothetical line that passes through contact regions 310-340 of the optical black pixel region 300 or 300′, from a portion of the active pixel region 200 to a boundary between the active pixel region 200 and the optical black pixel region 300 or 300′.

The first cross-section may include a substrate 510 and a light incident region 560. In addition, the first cross-section 500 may be divided into a left active pixel region and a right optical black pixel region. Each active pixel (AP) of the active pixel region may have some characteristics (e.g., the presence or absence of the optical filter, and the presence or absence of the light blocking layer) different from those of each optical black pixel OBP of the optical black pixel region. In some implementations, other than those characteristics, each active pixel (AP) of the active pixel region may have a structure and size that is identical or similar to those of the optical black pixel OBP of the optical black pixel region.

The substrate 510 may be a semiconductor substrate, and may include a top surface and a bottom surface facing away from each other. In some implementations, the bottom surface of the substrate 510 may be defined as a front side, and the top surface of the substrate 510 may be defined as a back side. Each of the top surface and the bottom surface may be referred to as a substrate surface. The image sensing device 100 may be formed to have a back side illumination (BSI) structure that receives incident light through the back side of the substrate 510. For example, the substrate 510 may be a P-type or N-type bulk substrate, may be a substrate formed by growing a P-type or N-type epitaxial layer on the P-type bulk substrate, or may be a substrate formed by growing a P-type or N-type epitaxial layer on the N-type bulk substrate.

The substrate 510 may include an impurity region 520, a photoelectric conversion element 530, a deep trench isolation (DTI) electrode 540, and a DTI insulation layer 550.

The impurity region 520 may be a region doped with specific conductive impurities (e.g., P-type or N-type impurities). For example, the impurity region 520 may be a P-type or N-type epitaxial layer.

The photoelectric conversion element 530 may be formed as a P-type or N-type doped region by implanting P-type or N-type impurities into the substrate 510. In some implementations, the photoelectric conversion element 530 may be formed by stacking a plurality of doped regions having different doping densities. The photoelectric conversion element 530 may be arranged across as large a region as possible to increase a fill factor indicating light reception (Rx) efficiency. The photoelectric conversion element 530 may correspond to the photodiode PD shown in FIG. 4.

At least a portion of the DTI electrode 540 and the DTI insulation layer 550 may be disposed in a DTI structure (i.e., a BDTI (backside DTI) structure) vertically recessed from one side (i.e., back side) of the substrate 510 through a DTI process on the back surface of the substrate 510.

The DTI electrode 540 may include a conductive material that fills a trench or recess formed in the substrate. In one example, the DTI electrode 540 is formed in the inner region of the DTI insulation layer 550 in the BDTI structure. For example, the DTI electrode 540 may be formed of metal, polysilicon or impurity-doped polysilicon. In addition, the DTI electrode 540 may be disposed between two adjacent pixels (or disposed in a boundary between two adjacent pixels).

The DTI electrode 540 may receive a bias voltage generated by the bias generator 180. As a negative bias voltage is applied to the DTI electrode 540, holes in the impurity region 520 may move to an interface between the BDTI (or a DTI insulation layer 550) and the impurity region 520, and may be accumulated at the interface.

As described above, since holes in the impurity region 520 may be accumulated at the interface between the BDTI (or DTI insulation layer 550) and the impurity region 520, a charge flow (i.e., dark current) of defective electrons that may be generated from the BDTI surface due to the DTI process can be suppressed.

The DTI insulation layer 550 may include an insulation material having a refractive index different from that of the impurity region 520. For example, the DTI insulation layer 550 may be formed of at least one of a silicon oxide layer, a silicon nitride layer, and a silicon oxynitride layer. The DTI insulation layer 550 may be formed in a manner that optical crosstalk in which light incident upon the active pixel AP or the optical black pixel OBP penetrates another adjacent pixel can be prevented, thereby preventing occurrence of optical crosstalk causing signal-to-noise ratio (SNR) reduction.

The BDTI that includes the DTI electrode 540 and the DTI insulation layer 550 may be disposed between the adjacent photoelectric conversion elements 530 of the adjacent pixels (APs or OBPs) to suppress the dark current and reduce the optical crosstalk.

The light incident region 560 may include an anti-reflection layer 570, an optical filter 575, an optical grid structure 580, a microlens 585, and a light blocking layer 590.

The anti-reflection layer 570 may allow light having penetrated the microlens 585 and the optical filter 575 to be efficiently incident upon the substrate 510 without being reflected from the back surface of the substrate 510. In addition, the anti-reflection layer 570 may be disposed between the substrate 510 and the light blocking layer 590. To this end, the anti-reflection layer 570 may have a higher refractive index than the microlens 585 and the optical filter 575 while having a lower refractive index than the substrate 510 and the DTI insulation layer 550. For example, the anti-reflection layer 570 may be formed of at least one of a silicon oxide layer, a silicon nitride layer, and a silicon oxynitride layer.

On the other hand, a DTI electrode extension portion 545 and a light blocking layer extension portion 595 may be disposed in the anti-reflection layer 570 disposed in the optical black pixel region.

In some implementations, the DTI electrode extension portion 545 may be a branch of the DTI electrode 540, and thus the DTI electrode extension portion 545 can be electrically coupled to the

DTI electrode 540. In addition, the DTI electrode extension portion 545 may extend from the DTI electrode 540 toward the light blocking layer 590. Referring to FIG. 5, the DTI electrode extension portion 545 may be disposed to cover at least a portion of the back surface of the substrate 510, and may be electrically coupled to the DTI electrode 540 disposed at both sides of the photoelectric conversion element 530 of the optical black pixel OBP. That is, the DTI electrode extension portion 545 may have a larger width than the optical black pixel OBP. In an implementation, the DTI electrode extension portion 545 has a larger width than only one optical black pixel OBP while having a smaller width than two optical black pixels (OBPs). In another implementation, the DTI electrode extension portion 545 may have a larger width than at least two optical black pixels (OBPs).

As the DTI electrode extension portion 545 is a branch of the DTI electrode 540, the DTI electrode extension portion 545 may be formed of the same materials as those of the DTI electrode 540.

In some implementations, the light blocking layer extension portion 595 may be a branch of the light blocking layer 590 that is structured to prevent light incident upon the optical black pixel region from being transmitted to the substrate 510, and may thus be electrically connected to the light blocking layer 590. In addition, the light blocking layer extension portion 595 may extend from the light blocking layer 590 toward the DTI electrode extension portion 545. As shown in FIG. 5, the light blocking layer extension portion 595 may be disposed to contact the DTI electrode extension portion while covering at least a portion of the DTI electrode extension portion 545. That is, the light blocking layer extension portion 595 may have a smaller width than the DTI electrode extension portion 545, other implementations are also possible, and it should be noted that the light blocking layer extension portion 595 may have a width equal to or larger than the width of the DTI electrode extension portion 545.

As the light blocking layer extension portion 595 is a branch of the light blocking layer 590, the light blocking layer extension portion 595 may have the same materials as those of the light blocking layer 590.

The DTI electrode extension portion 545 may protrude from the DTI electrode 540, and the light blocking layer extension portion 595 may protrude from the light blocking layer 590. Thus, the protruding DTI electrode extension portion 545 and the protruding light blocking layer extension portion 595 may be in contact with each other while being formed in a plug structure, so that the resultant DTI electrode extension portion 545 and the resultant light blocking layer extension portion 595 can be electrically in contact with each other. In this case, a region where the DTI electrode extension portion 545 is in contact with the light blocking layer extension portion 595 may correspond to the contact regions 310-340 shown in FIG. 2 or FIG. 3.

As the DTI electrode extension portion 545 and the light blocking layer extension portion 595 are connected to each other in a plug structure, the contact regions can have any shape and position in the optical black pixel region.

The bias voltage generated by the bias generator 180 of FIG. 1 may be transmitted to the light blocking layer 590 of the optical black pixel region, and the light blocking layer 590 may transmit the bias voltage to the DTI electrode 540 of the optical black pixel region through the DTI electrode extension portion 545 and the light blocking layer extension portion 595. As the DTI electrode 540 of the optical black pixel region is connected to the DTI electrode 540 of the active pixel region, the DTI electrode 540 of the active pixel region may receive the bias voltage as an input.

In some implementations, since the light blocking layer 590 is used to apply the bias voltage to the DTI electrode 540, the bias voltage can be effectively applied to the DTI electrode 540 without addition of a separate voltage transfer structure.

In addition, since the DTI electrode 540 and the light blocking layer 590 are connected to each other through the plug structure, the DTI electrode 540 and the light blocking layer 590 can be connected to each other.

In some implementations, the DTI electrode extension portion 545 and the light blocking layer extension portion 595 can be formed as will be discussed below. After the BDTI (e.g., the trench or recess) of the substrate 510 is sequentially filled with the DTI insulation layer 550 and the DTI electrode 540, the remaining area other than the DTI electrode extension portion 545 from among conductive materials disposed over the substrate 510 may be selectively etched and removed. Thereafter, the anti-reflection layer 570 may be disposed, and a region corresponding to the light blocking layer extension portion 595 may be selectively etched. Thereafter, the conductive materials for forming the light blocking layer 590 and the optical grid structure 580 are disposed over the anti-reflection layer 570, resulting in formation of the light blocking layer extension portion 595.

The optical filter 575 may be formed over the anti-reflection layer 570, and may selectively transmit light (e.g., red light, green light, blue light, magenta light, yellow light, cyan light, white light, or others) having a wavelength band to be transmitted. In some implementations, when the active pixel AP corresponds to a depth pixel, the optical filter 575 may be omitted or may be replaced with an infrared (IR) filter.

The optical grid structure 580 may be disposed between the adjacent optical filters 575 to prevent optical crosstalk between the adjacent optical filters 575. In some implementations, the optical grid structure 580 may include a metal material (e.g., tungsten) having a high light absorption rate.

Each of the microlenses 585 may be formed over the optical filter 575 and the light blocking layer 590, and may increase the light gathering power of incident light, improving the light reception (Rx) efficiency of the photoelectric conversion element. The microlens 585 may be arranged to correspond to one active pixel or one optical black pixel OBP. In another embodiment, if the active pixel AP corresponds to a phase detection autofocus (PDAF) pixel, the microlens 585 may be arranged to correspond to two or more active pixels (APs).

The light blocking layer 590 may be disposed over the entire optical black pixel region to block incident light from passing therethrough. The light blocking layer 590 may be spaced apart from the back surface of the substrate 510, and may be electrically connected to the DTI electrode 540 of the substrate 510 through the light blocking layer extension portion 595 of the plug structure. The light blocking layer 590 may be formed of a metal material (e.g., tungsten, copper, silver, aluminum, titanium) having a high light absorption rate and high conductivity.

As described above, the light blocking layer 590 may be connected to the light blocking layer extension portion 595 of the plug structure. The light blocking layer 590 may receive a bias voltage from the bias generator 180 of FIG. 1, and may transmit the bias voltage to the DTI electrode extension portion 545 through the light blocking layer extension portion 595.

The light blocking layer 590 may be formed together with the optical grid structure 580 using only one process, such that the light blocking layer 590 may have the same height as the optical grid structure 580 while being formed of the same material as the optical grid structure 580.

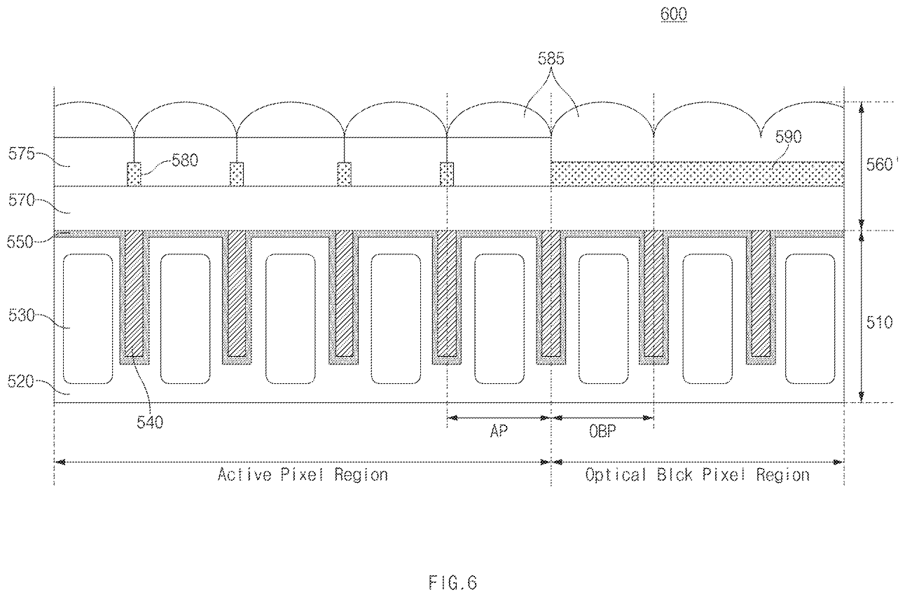

FIG. 6 is a cross-sectional view illustrating an example of a second cross-section 600 of the pixel array shown in FIG. 2 or FIG. 3.

Referring to FIG. 6, the second cross-section 600 may correspond to a cross-section of the pixel array 110-1 taken along line B1-B1′ or B2-B2′ depicted in the pixel array 110-1 of FIG. 2. Alternatively, the second cross-section 600 may correspond to a cross-section of the pixel array 110-2 taken along line D-D′ depicted in the pixel array 110-2 of FIG. 3. The line B1-B1′ or B2-B2′ or the line D-D′ may be a hypothetical line that passes through contact regions 310-340 of the optical black pixel region 300 or 300′, from a portion of the active pixel region 200 to a boundary between the active pixel region 200 and the optical black pixel region 300 or 300′.

The second cross-section 600 may include a substrate 510 and a light incident region 560′.

In some implementations, the second cross-section 600 may have some characteristics different from those of the first cross-section 500 shown in FIG. 5. In some implementations, the second cross-section 600 may have a structure that is similar or identical to those of the first cross-section 500 shown in FIG. 5. The second cross-section 600 shown in FIG. 5 will be discussed to clarify characteristics different from those of the first cross-section 500 shown in FIG. 5.

The DTI electrode extension portion 545 (see FIG. 5) and the light blocking layer extension portion 595 (see FIG. 5) may not be disposed in the anti-reflection layer of the light incident region 560′. In other words, the second cross-section 600 may not include a structure for electrically interconnecting the DTI electrode 540 and the light blocking layer 590.

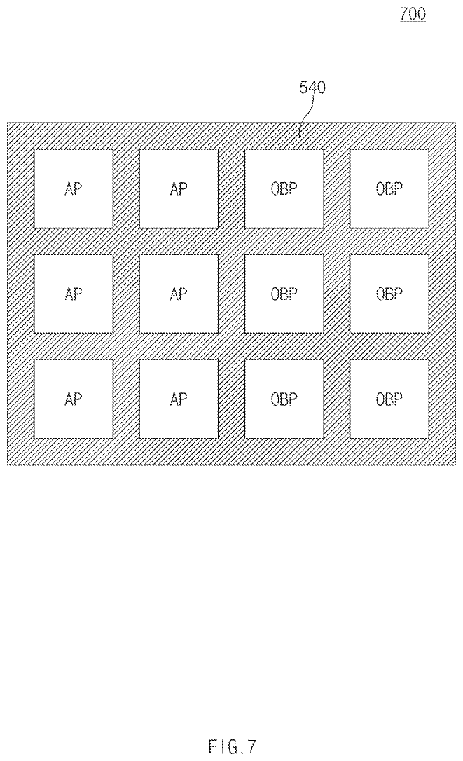

FIG. 7 is a schematic diagram illustrating an example of some regions of the pixel array.

Referring to FIG. 7, a portion 700 of the pixel array 110 shown in FIG. 1 may include some active pixels (AP) and some optical black pixels (OBP) that are arranged about a boundary between the active pixel region and the optical black pixel region. For convenience of description and better understanding of the disclosed technology, it should be noted that the active pixels (AP) and the optical black pixels (OBP) shown in FIG. 7 represent a region other than the DTI electrode 540. Accordingly, as shown in FIG. 7, the DTI electrode 540 is formed to surround each active pixel AP and each optical black pixel OBP.

Although the cross-sectional view shown in FIG. 5 or FIG. 6 illustrates that the plurality of DTI electrodes 540 is arranged while being separated from each other, other implementations are also possible. For example, as can be seen from FIG. 7, the DTI electrode 540 arranged to surround each active pixel AP and each optical black pixel OBP may have a mesh structure such that the corresponding the DTI electrodes 540 are connected to each other.

Accordingly, the DTI electrode 540 of the optical black pixel region configured to receive the bias voltage through the contact region disposed in the optical black pixel region may transmit a bias voltage to the DTI electrode 540 of the active pixel region.

In some implementations, the DTI electrode 540 disposed in the pixel array 110 may be divided into a plurality of mesh structures rather than only one mesh structure. In this case, different bias voltages may be applied to the DTI electrode of each mesh structure through the contact regions isolated from each other as shown in FIG. 2 or FIG. 3. Because there occurs a difference in the amount of light rays between the respective positions within the pixel array 110 depending on characteristics of an objective lens module (not shown) configured to converge incident light and transmit the converged light to the pixel array 110, the above-described method can be efficiently applied to the case where there occurs a difference in the amount of dark current between the respective regions of the pixel array 110.

For example, a first bias voltage having a relatively high level may be applied to some DTI electrodes of the active pixel region where a relatively large amount of dark current occurs, and a second bias voltage having a relatively low level may be applied to other DTI electrodes of the active pixel region where a relatively small amount of dark current occurs. As a result, the amount of dark current generated throughout the entire pixel array 110 may be equalized, so that noise components caused by such dark current can be easily removed.

As is apparent from the above description, the image sensing device based on some implementations of the disclosed technology has an optimum structure for reducing crosstalk between pixels.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a substrate including a substrate surface and a trench extending from the substrate surface;
a plurality of photoelectric conversion elements formed in the substrate and operable to convert incident light into photocharge;
an electrode formed in the trench and configured to receive a bias voltage for suppressing a dark current; and
a light blocking layer formed over the substrate surface of the substrate to block light from transmitting therethrough, and configured to be electrically conductive to receive the bias voltage and transmit the received bias voltage to the electrode.

2. The image sensing device according to claim 1, further comprising:
an anti-reflection layer disposed between the substrate and the light blocking layer;
wherein the anti-reflection layer includes:
an electrode extension portion extending from the electrode toward the light blocking layer; and
a light blocking layer extension portion extending from the light blocking layer toward the electrode extension portion.

3. The image sensing device according to claim 2, wherein the electrode extension portion and the light blocking layer extension portion are in contact with each other in the anti-reflection layer.

4. The image sensing device according to claim 2, wherein the electrode extension portion has a larger width than each pixel disposed in the substrate.

5. The image sensing device according to claim 4, wherein the light blocking layer extension portion has a smaller width than the electrode extension portion.

6. The image sensing device according to claim 2, wherein the light blocking layer extension portion is a branch extending from the light blocking layer.

7. The image sensing device according to claim 2, wherein the electrode extension portion is a branch extending from the electrode.

8. The image sensing device according to claim 1, wherein the light blocking layer includes tungsten.

9. The image sensing device according to claim 1, wherein the bias voltage is a negative voltage.

10. The image sensing device according to claim 1, further comprising:
an active pixel region that includes a plurality of active pixels to generate a signal that indicates an intensity of the incident light; and
an optical black pixel region that includes a plurality of optical black pixels to generate a signal that does not indicate the intensity of the incident light,
wherein each of the active pixels and the optical black pixels includes one of the photoelectric conversion elements.

11. The image sensing device according to claim 10, wherein:
the optical black pixel region is disposed to surround the active pixel region, and
the light blocking layer is disposed in the optical black pixel region.

12. The image sensing device according to claim 10, wherein the optical black pixel region includes:
a first contact region disposed in a lateral side of the active pixel region; and
a second contact region disposed in an upper side or a lower side of the active pixel region,
wherein each of the first contact region and the second contact region includes a region where the light blocking layer and the electrode are electrically connected to each other,
wherein
the first contact region has a shorter length than the lateral side of the active pixel region, and
the second contact region has a shorter length than the upper side or the lower side of the active pixel region.

13. The image sensing device according to claim 10, wherein the optical black pixel region includes:
a third contact region disposed in a lateral side of the active pixel region; and
a fourth contact region disposed in an upper side or a lower side of the active pixel region,
wherein each of the third contact region and the fourth contact region includes a region where the light blocking layer and the electrode are electrically connected to each other,
wherein
the third contact region has a longer length than the lateral side of the active pixel region, and
the fourth contact region has a longer length than the upper side or the lower side of the active pixel region.

14. The image sensing device according to claim 10, wherein:
the electrode is disposed to surround each of the active pixels and each of the optical black pixels,
wherein the electrode surrounding each of the active pixels and the electrode surrounding each of the optical black pixels are arranged in a mesh structure.

15. An image sensing device comprising:
a pixel array including an active pixel region and an optical black pixel region, the active pixel region including a plurality of active pixels that receive incident light and generate a signal that indicates an intensity of the received incident light, the optical black pixel region including a plurality of optical black pixels that include a light blocking layer to block light from entry and generate a signal independent of the intensity of the incident light received by the optical black pixel;
an electrode structured to include vertically extended portions disposed between adjacent pixels of active pixels and optical black pixels, and configured to receive a bias voltage for suppressing a dark current generated in at least one of the active pixel region or the optical black pixel region; and
a bias generator configured to generate the bias voltage,
wherein the light blocking layer in the optical black pixel region is configured to be electrically conductive to receive the bias voltage from the bias generator and transmit the received bias voltage to the electrode.

16. The image sensing device according to claim 15, wherein the electrode includes a horizontally extended portion disposed between at least one of the optical black pixels and the light blocking layer disposed over the at least one of the optical black pixels.

17. The image sensing device according to claim 16, further comprising a light blocking layer extension portion disposed between the light blocking layer and the horizontally extended portion of the electrode.

18. The image sensing device according to claim 17, further comprising an anti-reflection layer disposed over the active pixel region and the optical black pixel region and below the light blocking layer.

19. The image sensing device according to claim 18, wherein the light blocking layer extension portion and the horizontally extended portion of the electrode are disposed in the anti-reflection layer.
